(19) United States
(12) Patent Application Publication
(10) Pub. No.: US 2012/0292788 A1
(43) Pub. Date: Nov. 22, 2012

(54) Chip stacking

(75) Inventor: Hoi Wai Choi, Hong Kong (CN)

(73) Assignee: The University of Hong Kong, Hong Kong (CN)

(21) Appl. No.: 13/506,839

(22) Filed: May 18, 2012

Related U.S. Application Data
(60) Provisional application No. 61/487,890, filed on May 19, 2011.

(51) Int. Cl. H01L 23/52; H01L 21/50

(52) U.S. Cl. 257/777; 438/109; 257/E23.141; 257/E21.499

(57) ABSTRACT

Methods and systems are provided to utilize and manufacture a stacked chip assembly. Microelectronic or optoelectronic chips of any dimensions are directly stacked onto each other. The chips can be of substantially identical sizes. To enable forming the stacked chip assembly, trenches are laser micro-machined onto the bottom surface of a chip to accommodate the bond wedge/ball and wire path of the chip beneath it. Consequently, chips can be tightly integrated without a gap and without having to reserve space for the bond wedges/balls.

### CROSS-REFERENCE TO RELATED APPLICATION

This application claims the benefit under 35 U.S.C. §119(e) of U.S. Provisional Patent Application No. 61/487,890, filed May 19, 2011, the contents of which are herein incorporated by reference in its entirety.

### BACKGROUND

1. Technical Field

The subject matter disclosed herein relates to the assembly of microelectronic and optoelectronic chips.

2. Description of Related Art

Vertical stacking of chips has become an important pursuit in the microelectronics industry. Due to an increasing demand for miniaturization of electronic components (such as memory card products) in the midst of growing functionality (such as faster speeds or storage capacities), more and more chips are required to fit into less and less package space. In the design of an integrated chip, more functionality or storage is generally equivalent to an increase in f transistor count, which translates into additional chip space. Since wafer processing is a two-dimensional process, the chip can only grow laterally in size to pack in more transistors.

One solution towards increasing transistor count in a limited space is chip stacking. This allows multiple chips to be stacked on top of each other without increasing lateral dimensions. This is also practical because chips are typically thin in height, and wafer thinning is a common practice in the microelectronics industry.

One of the hurdles of chip stacking is the consideration of wire bonds from the chip to the package. In a typical integrated circuit chip, there are numerous bond pads which must be externally connected via wire bonds to establish electrical connections. Due to the finite height of the bond wedge or ball (depending on the type of wire bonding) and the wire height associated with the bond, chips cannot be stacked onto each other without consideration of the bond wedges or balls used to establish the electrical connection.

There are two commonly used conventional methods of enabling chip stacking. The first method, as illustrated in FIG. 1A, relates to the stacking of chips 10, 12 of non-identical dimensions on a substrate 14. As shown in FIG. 1A, chip sizes become increasingly larger going down the stack. This allows for an area 10′ at the edge of chip 10 to protrude from below higher chip 12 in the stack to accommodate the wire-bonds 11. However, the arrangement of chips by creating and layering chips from smallest to largest reduces flexibility because chips of specific dimensions in each layer must be used. Also, chips towards the lower end of a stack are made larger than they need to be according to the devices formed therein, thus wasting chip space.

The second commonly adopted method is the introduction of spacer layers 16, as shown in FIG. 1B. Such spacer layers are arbitrary layers of similar materials that are smaller in area than the actual chips 10, 12. The spacer layers are bonded in between the actual chips, thus creating a recess area 12′ at the edge of the active chips to accommodate the wire bonds 11.

Although the size of the chip is not as restricted as in the first method, the second method is not without its own drawbacks. For example, the spacer layer incurs additional costs, additional height, and also impedes heat conduction from the chip to the package.

In either case, the bond pads must be located near the edges of the chips in order to access the bond pads of chips in the stack.

In addition to the use of chip stacking for integrated circuits, chip stacking has also been introduced to optoelectronic devices.

For example, light-emitting diode (LED) chips emitting at different wavelengths can be stacked on top of each other to produce a color-mixed output, provided that the chips are transparent (e.g., the chip at the bottom of the stack can be translucent). Light emitted from each chip is coupled to the chip above, and is naturally mixed with the light emitted from that chip due to the overlapping of the optical pathway. Light emitted from all chips are mixed together and emitted through the top chip in the stack, giving polychromatic and color-tunable light. This requires lateral emission from individual chips to be minimized.

Using either of the two described methods of chip stacking can give rise to significant leakage of light from the individual LED chips due to exposure of the edges meant to accommodate the wire bonds of each chip in a stack.

### SUMMARY OF THE INVENTION

The present invention is directed a method of stacking integrated circuit chips so that wire bond interconnections of each chip with the surrounding circuit are accommodated in minimal space. It also relates to a vertically stacked chip assembly.

In an illustrative embodiment the method includes the steps of attaching a first chip to a base of a package and forming a first wire bond electrically connecting a first pad on a top surface of the first chip to a first pad of the package. Then a first trench is formed in a bottom surface of a second chip at a location corresponding to a portion of the first wire bond connected to the first pad of the first chip.

The second chip is attached to the first chip such that the first trench in the second chip is aligned over the portion of the first wire bond connected to the first pad of the first chip. Then a second wire bond is formed electrically connecting a second pad on a top surface of the second chip to a second pad of the package.

When three chips are stacked, in the next step a second trench is formed in a bottom surface of a third chip at a location corresponding to a portion of the second wire bond connected to the second pad of the second chip. Then the third chip is attached to the second chip such that the second trench in the third chip is aligned over the portion of the second wire bond connected to the second pad of the second chip. Finally, a third wire bond is formed electrically connecting a third pad on a top surface of the third chip to a third pad of the package.

The trenches in the bottoms of the chips can be created by direct-write laser micromachining. In particular, the trenches can be formed by focusing a laser beam to a spot size corresponding to a desired width of the trench and linearly trepanning the laser beam to ablate the bottom surface of a chip along a path corresponding to the first pad of the chip below it in the stack.

The method of the invention can be used to create a vertically stacked chip assembly of three different light emitting devices which can have the light from each chip pass through the chips on top of it. The light from the different chips can be collected an emitted from the upper surface of the top chip. Thus individual control of the chips can result in a variety of color outputs from the stack. Using trenches of the present invention allows for a tight fit of the chips of the stack and eliminates lateral light leakage.

### BRIEF DESCRIPTION OF DRAWINGS

Non-limiting and non-exhaustive aspects are described with reference to the following figures, wherein like reference numerals refer to like parts throughout the various figures unless otherwise specified:

FIGS. 1A and 1B illustrate two common die stacking approaches;

FIG. 2 is a flow chart showing of a method of forming a vertical stack of chips in accordance with an embodiment of the invention;

FIG. 3 is a diagram of a laser micromachining setup with a laser, beam expander, focusing lens, and motorized stages used in certain embodiments of the invention;

FIG. 4 illustrates trepanning of a laser beam across a substrate to form a recess area serving as a trench in accordance with an embodiment of the invention;

FIG. 5 illustrates the assembly of two chips in accordance with an embodiment of the invention;

FIG. 6 is a schematic diagram of a stack of red, green and blue light-emitting diodes, assembled in accordance with an embodiment of the invention by aligning the wire bond wedges/balls into the laser micro-machined trenches on the bottom face of the chip above;

FIG. 7 is a color photograph of a plan view of a laser micro-machined trench formed on the sapphire face of a GaN-based LED chip using an ultraviolet laser at a wavelength of 349 nm;

FIG. 8 is a color photograph of a greatly enlarged cross-sectional view of the stacking of a die with a laser micro-machined trench on top of a regular die of an embodiment of the invention;

FIG. 9 is a color microphotograph of an assembled stack of red, green and blue light-emitting diodes in accordance with an embodiment of the invention;

FIGS. 10A-10C are color microphotographs showing uniform color-mixing achieved with the present stacking design where leakage of light from individual chips is minimized, emitting different shades of a white range extending from cool white to warm white; and

FIGS. 11A-11I are color photographs illustrating a wide range of colors emitted by a stacked design implemented by the present approach.

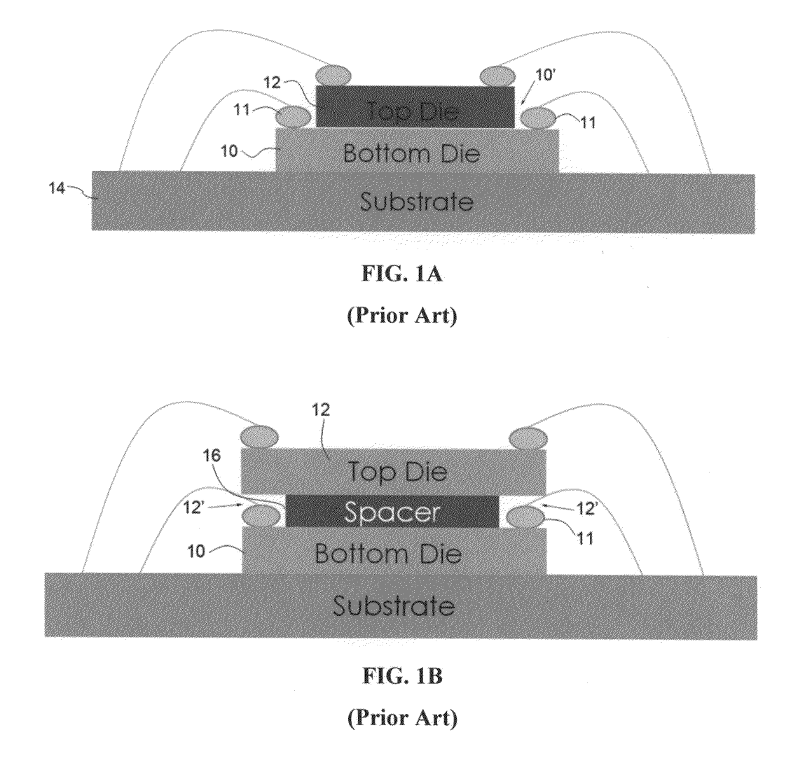

The patent or application file contains at least one drawing executed in color and photographs. Copies of this patent or patent application publication with color drawing(s) will be provided by the Office upon request and payment of the necessary fee.

### DETAILED DESCRIPTION

Some exemplary methods and systems are described herein that may be used to utilize and manufacture an assembly comprising a stack of microelectronic or optoelectronic chips. A process of manufacturing the same is also provided. For microelectronic applications, stacked microelectronic chips may be used to increase transistor count in a given volume. In addition, for optoelectronic applications, stacked optoelectronic chips may be used to produce a color-mixed or color-tunable device.

Stacking of microelectronic circuits may be exploited to increase circuit functionality. As an example, stacking of memory chips can be used to increase overall storage capacity without increasing the device footprint.

Each chip in a stack is connected to an external circuit or other integrated circuit chips. This is achieved by wire bonding to the bond pads on a chip. Wire bonding produces a bond wedge or ball (of finite height) at the location of the pad, and also a bond wire between the bond pads on the chip and on the package. As a result, a second chip cannot easily be attached on top of a first chip without affecting the bond wires of the first chip.

In accordance with certain embodiments of the invention, a trench is formed at the bottom of the second chip above the first chip to accommodate the bond wedge/ball and the wire path of the first chip. Advantageously, using this approach, the bond pads can be located anywhere on the chip and are not required to be located near the edges of the chips.

According to an embodiment of the invention, a method of making a stacked chip assembly includes forming an electrical connection via wire-bonds from bond pads of a first chip of the stacked chip assembly to pads of a package for the stacked chip assembly; forming trenches on the bottom of a second chip at locations corresponding to a bond edge or ball of the wire-bond of the first chip; and attaching the second chip to the first chip on top of the first chip by aligning the bond wedge or ball of the first chip to a corresponding trench in the second chip. The second chip can be fixed to the first chip by, for example, epoxy or capillary bonding. This procedure can be repeated for each additional chip in the stacked chip assembly to build a vertical stack of chips. In addition, a base can be provided for attachment and/or support of the first chip in the package for the stacked chip assembly. The first chip can be attached to the base before forming the wire-bonds for the first chip.

The size of each chip is not dependent on its position in the stacked chip assembly and no spacer is required between chips. Further, the size of each chip can correspond to the area required for the circuit or structure formed thereon. In certain embodiments, each chip in the stacked chip assembly may be substantially identical in area to the other chips in the stacked chip assembly.

The subject method is applicable to stacking a variety of chips including microelectronic and optoelectronic circuits and devices.

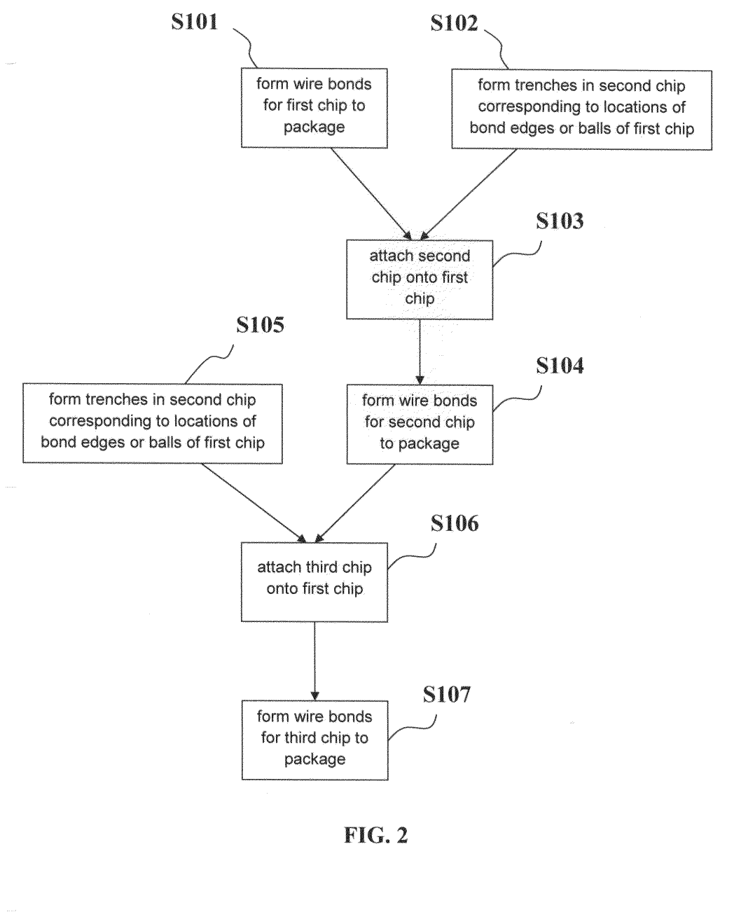

In one example, referring to FIG. 2, a method of making a stacked chip assembly of three chips is shown. First, wire bonds are formed to connect pads of a first chip to pads of the package or base for the stacked chip assembly (S201). The wire bonds can be formed using a wedge/ball wire bonder. In addition, trenches are formed in a second chip at regions corresponding to locations of bond edges or balls of the wire bonds of the first chip (S202). Steps S201 and S202 can be performed in any order and may be performed simultaneously. The second chip is then attached to the first chip such that the trenches in the second chip are aligned over the bond edges or balls of the wire bonds of the first chip (S203). The second chip can be fixed to the first chip, for example, via epoxy or capillary bonding. Wire bonds can then be formed to connect pads of the second chip to pads of the package for the stacked chip assembly (S204). Trenches can be formed in a third chip at regions corresponding to locations of bond edges or balls of the wire bonds of the second chip (S205). Step S205 can be performed before, during, or after step S204. The third chip having the trenches can then be attached to the second chip such that the trenches in the third chip are aligned over the bond edges or balls of the wire bonds of the second chip (S206). The third chip can be fixed to the second chip, for example, via epoxy or capillary bonding. Wire bonds can then be formed to connect pads of the third chip to pads of the package or base for the stacked chip assembly (S207).

In accordance with exemplary embodiments of the invention, the trenches are formed by direct-write laser micromachining. The laser micromachining eliminates the need for photolithographic patterning of a masking layer and/or performing a wet or dry etch.

A laser micromachining setup suitable for the enabling assembly of a stack of chips in accordance with various embodiments of the present invention includes a high-power laser, a laser beam expander for beam expansion and collimation, focusing optics to focus the beam to a required beam diameter, and either beam steering optics or motorized stage scanning electronics for beam trepanning. The laser beam is focused to a spot size equivalent to the desired width of the trench, followed by scanning the beam across to form the desired trench.

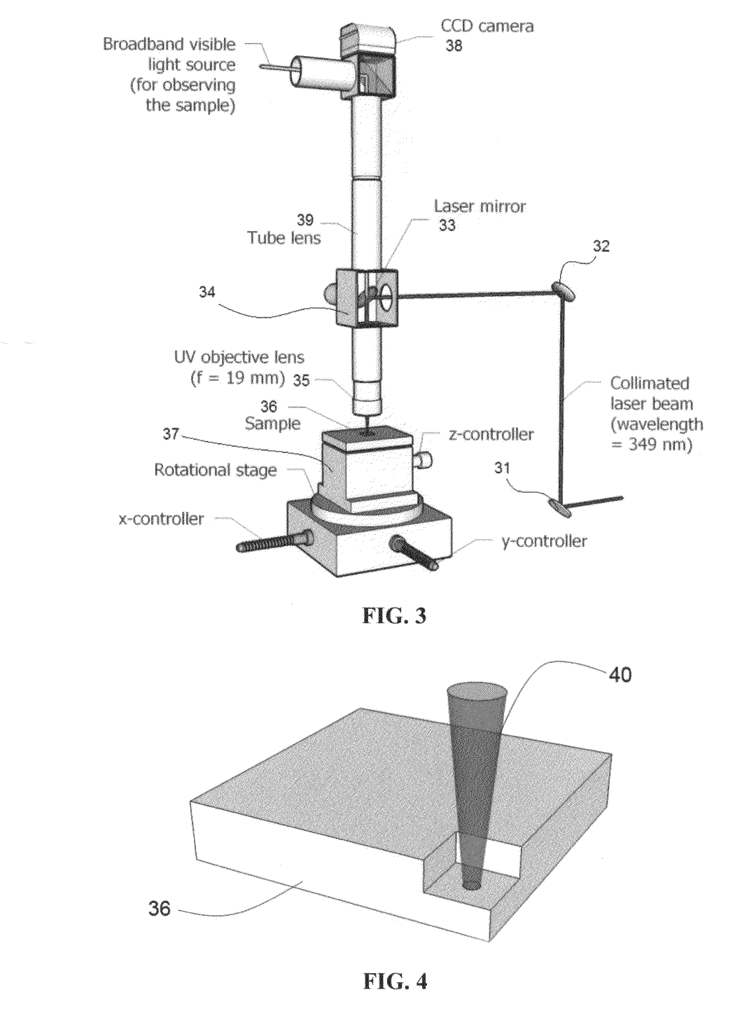

FIG. 3 illustrates a diagram of an exemplary laser micromachining set-up used in accordance with a specific embodiment of the subject invention. Referring to FIG. 3, light emitted from a laser (not shown) is steered by mirrors including first mirror 31, second mirror 32, and laser mirror 33. Collimating optics may be positioned in the light path of the laser before the light reaches the first mirror 31. Alternately, the collimating optics can be positioned in the light path of the laser between the first mirror 31 and the second mirror 32. The collimated laser beam is steered through a spatially defining aperture 34 to be passed through an UV objective lens 35 that focuses the beam onto the sample surface being ablated. Here, the sample can be a chip substrate. The sample 36 is positioned on a stage 37 that can be controlled in three dimensions (x, y, and z). To observe the samples, a broadband visible light source (not shown), CCD camera 38 and tube lens 39 may optionally be included.

When performing the laser micromachining, the steering using the optics such as the mirrors 31, 32, and 33, and/or the stage 37 can trepan the beam to form a desired shaped trench. In particular, a laser beam is focused to a spot size corresponding to the desired width of the trench, and a trench is formed by laser ablation by linearly trepanning the laser beam.

For example, referring to FIG. 4, the UV laser beam 40 is focused onto the sample 36, resulting in ablation of the sample to a particular depth in the substrate of the sample. The steering (i.e., trepanning) is used to create the particular shape of the trench. The sample shown in FIG. 4 is a cross-section of the sample substrate along a line created by steering the UV beam 40 in the x-direction. It should be understood that embodiments are not limited thereto. For example, a trench can be formed at an angle (i.e. have an x-direction and y-direction component). The laser beam is selected to have sufficient energy and be of suitable wavelength for the ablation, which depends on parameters of the material itself, such as bandgap energy and mechanical hardness.

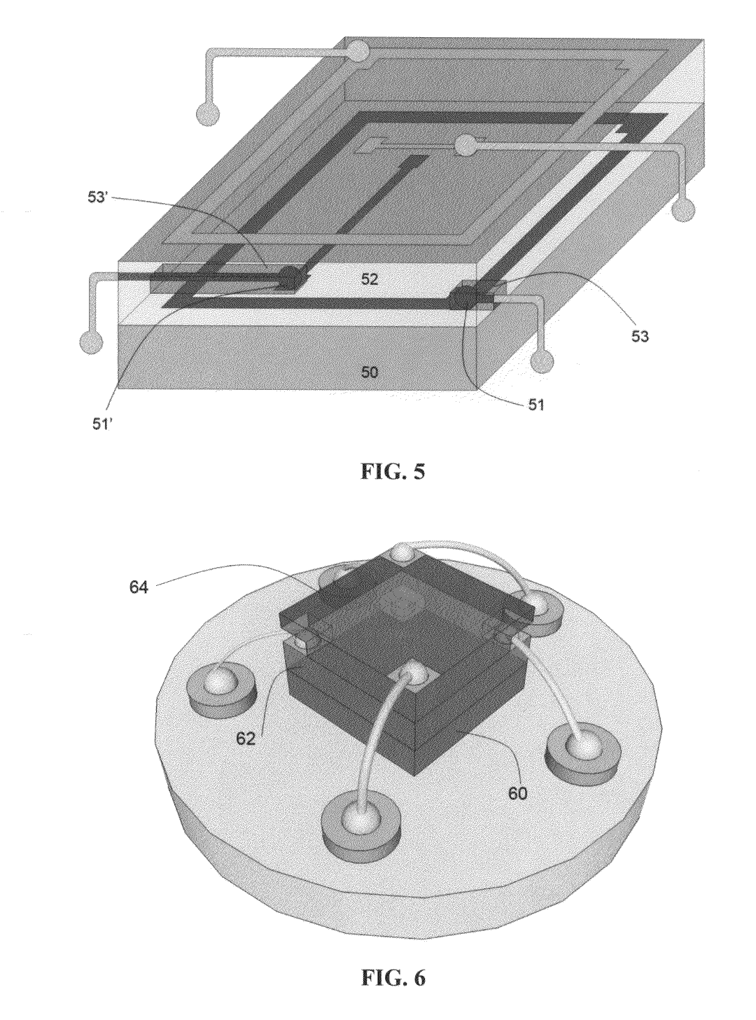

FIG. 5 illustrates the assembly of two chips in accordance with an embodiment of the invention. Referring to FIG. 5, a first chip 50 having wire bond wedges or balls 51 is stacked thereon with a second chip 52 with laser-micro-machined trenches 53 on its bottom face. The second chip 52 having the laser-micro-machined trenches is placed on top of the first chip 50 with wire bond wedges/balls such that the trenches 53 of the second chip are aligned to the wire bond wedges or balls 51 of the first chip. In this embodiment one of the wire bond wedges or balls 51′ and its matching trench 53′ are located away from the edge of the chips. In such a case, at least a reduced size trench must extend to the edge of the chips to accommodate the wire bonds connecting to the substrate. Because the trenches of the second chip are aligned to the position of the bond wedges/balls of the first chip, the two chips can be assembled without a gap.

According to certain embodiments, the depth of a trench formed in a bottom facing surface of a chip is made to be equal to or larger than the height of the bond wedge or ball to be fitted in.

By forming the trench equal to or larger than the height of the bond wedge or ball to be fitted in, the bond wedge/ball, together with the wire path from the wedge/ball bonding the wire to a pad on the first chip to an external pad, fits snugly into the laser micro-machined trench.

Since the protruding wedge/ball fits into the sunken trenches, the chips are naturally aligned in place.

In another embodiment, light-emitting diode chips of different emission wavelengths are stacked on top of each other to form a polychromatic device. FIG. 6 is a diagram of a stack of light-emitting diode (LED) chips in accordance with an embodiment of the invention.

Referring to FIG. 6, a red LED device 60, a green LED device 62, and a blue LED 64 device are stacked on top of each other with the red being at the bottom, green in the middle and blue at the top. Advantageously, by using an embodiment of the stacking method described above, the three chips can be of substantially identical dimensions. In addition, the chips can be stacked without a gap.

In a specific embodiment, the red LED is an AlInGaP based red LED with a translucent and electrically conducting substrate. The substrate of the red LED chip, also serving as an n-type electrode, is bonded to the package. Wire-bonds are established from the top of the red LED and are connected as the p-type electrodes. The red LED chip can be in the form of a regular die.

The middle green LED is an InGaN-based LED grown on transparent sapphire substrate. Because the sapphire substrate is non-conducting, both n-type and p-type electrodes are located on the top surface. Thus, at least two bond wires, one n-type and one p-type, are provided to electrically connect the device to the package to bias the device.

To accommodate the bond wedge/ball of the red LED chip beneath the green LED, a trench is formed on the underside of the green LED chip. That is, in the sapphire substrate. The location of the trench is formed to correspond to the location of the bond wedge/ball and the wire path for the red LED.

To effectively laser micro-machine sapphire, a high-power ultra-violet laser with a pulse width of the order of a nanosecond or shorter may be used.

With the trench formed, the green chip can be attached to the top of the red chip with the aid of a die-bonder. The presence of the trench guides the green LED chip into place. The chips can be fixed in position using an optically transparent epoxy.

In the same way, a blue LED chip, such as an InGaN based LED chip on a sapphire substrate, is attached to the top of the assembly.

FIG. 7 shows a plan view of a laser micromachined trench 71 across the trench path formed on the sapphire face of an InGaN based LED chip. The trench was formed by laser micromachining using an ultraviolet laser at a wavelength of 349 nm, which is effective in ablating a sapphire substrate.

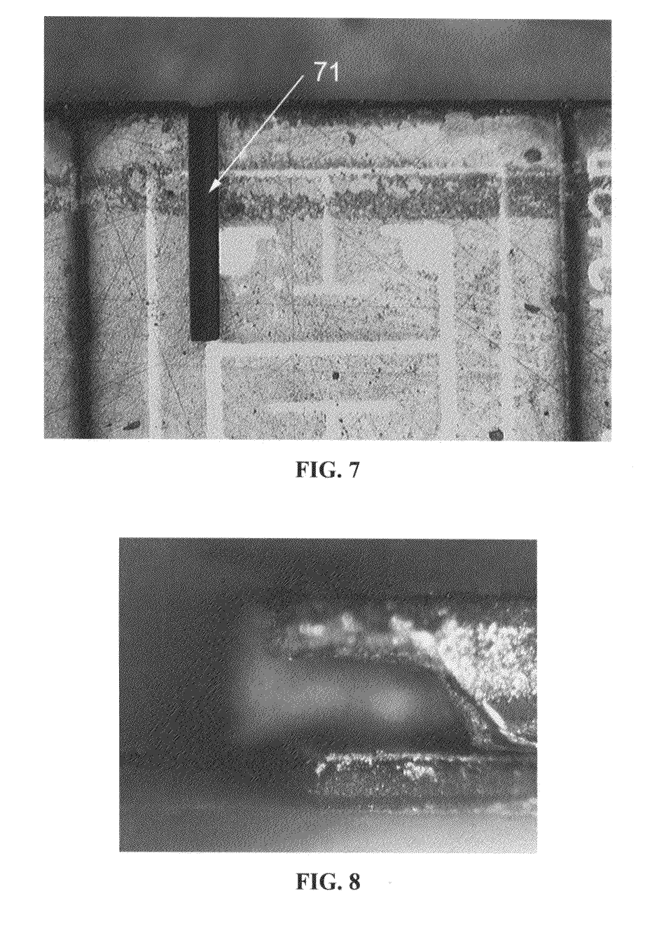

FIG. 8 shows a cross-sectional view of the laser micromachined trench along the trench path after being stacked on top of a regular die. The regular die in the image is a red LED chip and the chip having the laser micromachined trench is a green LED chip.

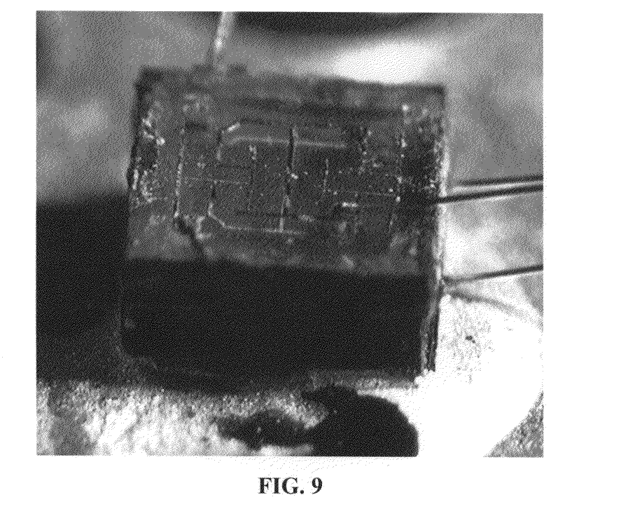

FIG. 9 provides a perspective view of the complete assembly for the LED chip stack. As shown in FIG. 9, the top chip (e.g., the blue LED chip) has a wire bond for both the p and n electrodes (wire bond foreground is clearly shown while wire bond in background is not in focus in the image). The middle chip (e.g., the green LED chip) wire bonds are not shown in the image, but a wire for the bottom chip (e.g., the red LED chip) is shown extending from a trench in a bottom facing surface of the middle chip. As shown in the image, chips having a same size (i.e. length and width) can be vertically stacked with minimal height while enabling pad connections of chips within the stack to be available.

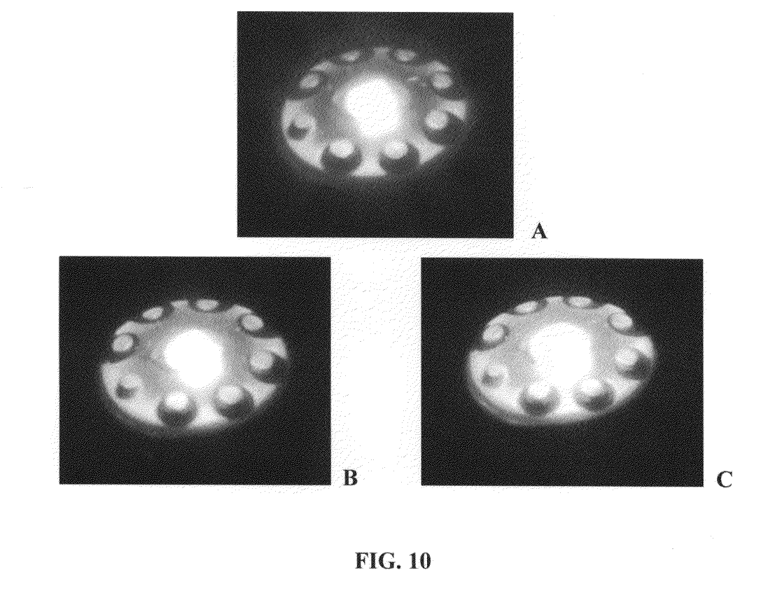

FIG. 10 provides images of the complete assembly while the chips are activated to emit white color. By minimizing leakage of light from individual chips, uniform color mixing and conformal color emission can be achieved. By controlling the proportions of red, green and blue light, different shades of white light emission can be achieved. Cool, neutral and warm white light with correlated color temperatures of 7100 K, 6100 K and 2400 K are illustrated in FIGS. 10A to 10C, respectively.

By individually adjusting the bias voltages of each of the chips, different intensities of red, blue and green light are emitted.

Since the LED chips are assembled as a stack, the light emitted from each chip passes through the chip(s) on top of it. Eventually, the light from different chips is emitted collectively from the top chip, creating an optically mixed effect.

By controlling the intensities of red, green and blue, the color of the optically-mixed output can be varied across the visible spectrum.

Using this stacking design, chips of identical dimensions are tightly stacked on top of each other, and wire bond wedges/balls are embedded in the stack without being exposed. As a result, the light emitting surface of every chip (except the top chip) is not exposed, and therefore light from individual chips will not leak from the side of the stack.

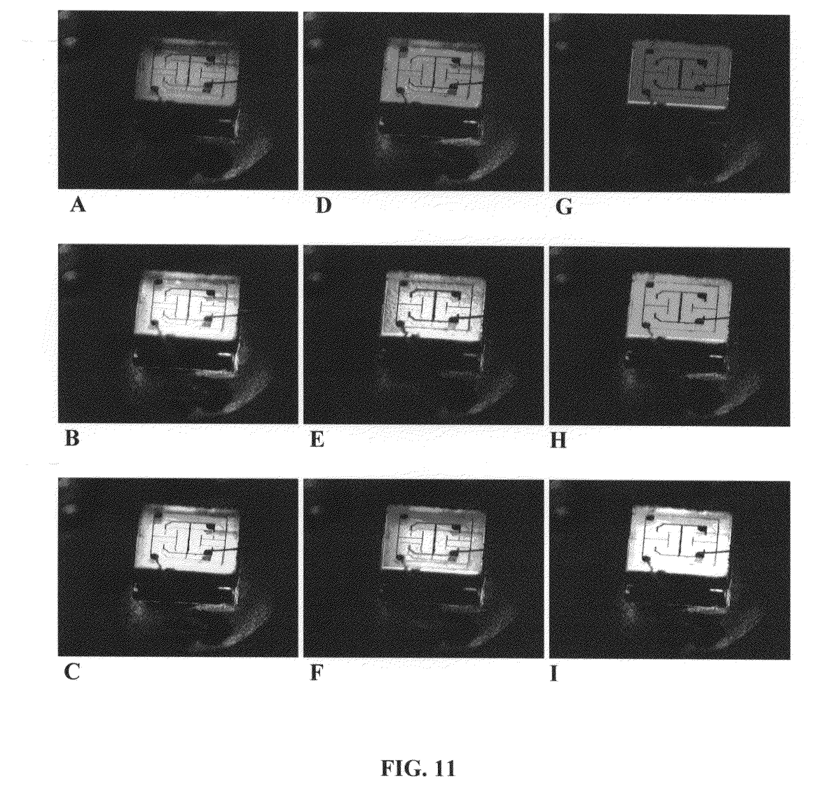

FIG. 11 illustrates the wide range of colors emitted by a stacked LED chip structure implemented in accordance with an embodiment of the invention. In FIG. 11, A shows a red color light, B shows an orange color light, C shows a yellow color light, D shows a green color light, E shows a purple color light, F shows a pink color light, G shows a blue color light, H shows a teal color light, and I shows a whitish color light.

According to certain embodiments of the invention, a light emitting device assembly is provided that includes a substrate or package as a base, a first LED chip on the base, a second LED chip on the first LED chip, and a third LED chip on the second LED chip. The first LED chip can be attached to the base via any suitable method known in the art. The second LED chip includes a trench in its lower surface that is aligned over a wire bond of the first LED chip, and the third LED chip includes a trench in its lower surface that is aligned over a wire bond of the second LED chip. Additional chips, each having a trench in its lower surface corresponding to a wire bond of a chip below, can be included in the light emitting device assembly.

According to one embodiment, the LED chips are stacked such that the emission wavelength of each chip increases as its position in the vertical stack becomes lower. For example, the third LED chip can emit light of a first wavelength, the second LED chip can emit light of a second wavelength larger than the first wavelength, and the first LED chip can emit light of a largest wavelength. The chips in the light emitting device assembly can be stacked on each other and adhered directly to the chip above and below in the stack. A transparent optical epoxy or liquid capillary bonding can be used. The capillary bonding may form ball bonds for bonding the two chips together. Advantageously, the air gap between the LED chips is minimized, resulting in improved optical transmission.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that the claimed subject matter not be limited to the particular examples disclosed, but that such claimed subject matter may also include all implementations falling within the scope of the appended claims, and equivalents thereof.

Any reference in this specification to “one embodiment,” “an embodiment,” “exemplary embodiment,” etc., means that a particular feature, structure, or characteristic described in connection with the embodiment is included in at least one embodiment of the invention. The appearances of such phrases in various places in the specification are not necessarily all referring to the same embodiment. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

It should be understood that the examples and embodiments described herein are for illustrative purposes only and that various modifications or changes in light thereof will be suggested to persons skilled in the art and are to be included within the spirit and purview of this application.

What is claimed is:

1. A method of chip stacking to form a chip assembly, the method comprising:
attaching a first chip to a base of a package;
forming a first wire bond electrically connecting a first pad on a top surface of the first chip to a first pad of the package;
forming a first trench in a bottom surface of a second chip at a location corresponding to a portion of the first wire bond connected to the first pad of the first chip;
attaching the second chip to the first chip such that the first trench in the second chip is aligned over the portion of the first wire bond connected to the first pad of the first chip; and
forming a second wire bond electrically connecting a second pad on a top surface of the second chip to a second pad of the package.

2. The method according to claim 1, wherein forming the first trench in the bottom surface of the second chip comprises performing direct-write laser micromachining.

3. The method according to claim 1, wherein forming the first trench in the bottom surface of the second chip comprises focusing a laser beam to a spot size corresponding to a desired width of the first trench and linearly trepanning the laser beam to ablate the bottom surface of the second chip along a path between a position on the second chip corresponding to the first pad of the first chip and an edge of the second chip.

4. The method according to claim 1, wherein forming the first trench in the bottom surface of the second chip comprises using a laser beam of sufficient power and suitable wavelength to ablate material of the bottom surface of the second chip.

5. The method according to claim 1, wherein the first trench has a depth equal to or greater than a height of a bond wedge or ball of the first wire bond to be fitted in.

6. The method according to claim 1, wherein the portion of the first wire bond connected to the first pad of the first chip over which the first trench in the second chip is aligned comprises a bond wedge or ball on the first pad of the first chip and a part of a wire of the first wire bond extending from the bond wedge or ball.

7. The method according to claim 1, wherein the first pad of the first chip is disposed on a central region of the first chip away from an edge of the first chip.

8. The method according to claim 1, wherein attaching the second chip to the first chip comprises directly attaching the second chip to the first chip using epoxy or capillary bonding.

9. The method according to claim 1, further comprising:
forming a second trench in a bottom surface of a third chip at a location corresponding to a portion of the second wire bond connected to the second pad of the second chip;
attaching a third chip to the second chip such that the second trench in the third chip is aligned over the portion of the second wire bond connected to the second pad of the second chip; and
forming a third wire bond electrically connecting a third pad on a top surface of the third chip to a third pad of the package.

10. A vertically stacked chip assembly comprising:
a first chip on a base, the first chip comprising a first bonding pad and a first wire bond connected to the first bonding pad and an external pad;
a second chip on the first chip, a bottom surface of the second chip facing a top surface of the first chip and comprising a first trench aligned over the first wire bond of the first chip such that a bond wedge or ball of the first wire bond is fitted in the first trench and a wire of the first wire bond is disposed along a path of the first trench and extends out of the first trench at an edge of the second chip to the external pad.

11. The vertically stacked chip assembly according to claim 10, wherein the first chip and the second chip have a substantially same length and width.

12. The vertically stacked chip assembly according to claim 10, wherein the second chip is directly attached to the first chip with an epoxy.

13. The vertically stacked chip assembly according to claim 10, wherein at least one of the first chip and the second chip comprises an integrated circuit formed therein.

14. The vertically stacked chip assembly according to claim 10, wherein the second chip further comprises a second bonding pad and a second wire bond connected to the second bonding pad and a second external pad, the assembly further comprising:
a third chip on the second chip, a bottom surface of the third chip facing a top surface of the second chip and comprising a second trench aligned over the second wire bond of the second chip such that a bond wedge or ball of the second wire bond is fitted in the second trench and a wire of the second wire bond is disposed along a path of the second trench and extends out of the second trench at an edge of the third chip to the second external pad.

15. The vertically stacked chip assembly according to claim 14, wherein the first pad of the first chip is covered by the second chip and the second pad of the second chip is covered by the third chip.

16. The vertically stacked chip assembly according to claim 14, wherein the first chip, the second chip, and the third chip have a substantially identical width and length.

17. The vertically stacked chip assembly according to claim 14, wherein the first chip is a first light-emitting device chip, the second chip is a second light-emitting device chip, and the third chip is a third light-emitting device chip.

18. The vertically stacked chip assembly according to claim 17, wherein the first light-emitting device chip emits light at a wavelength larger than the second light-emitting device chip and the second light-emitting device chip emits light at a wavelength larger the third light-emitting device chip.

19. The vertically stacked chip assembly according to claim 17, wherein each of the first light-emitting device chip, the second light-emitting device chip, and the third light-emitting device chip has n-type and p-type interconnects externally connected for individual control and driving.

20. The vertically stacked chip assembly according to claim 19, wherein the n-type interconnect of the first light-emitting device chip is provided by a substrate of the first light-emitting device chip, the substrate of the first light-emitting device chip being bonded to the base, wherein the p-type interconnect of the first light-emitting device chip is connected externally via the first wire bond;
wherein the n-type and p-type interconnects are connected externally via the second wire bond and another second wire bond of the second light-emitting device chip; and
wherein the n-type and p-type interconnects are connected externally via a corresponding one of a plurality of third wire bonds connected to third bonding pads on a top surface of the third light-emitting device chip.
